(19) United States
(12) Patent Application Publication
(10) Pub. No.: US 2021/0359260 A1
(43) Pub. Date: Nov. 18, 2021

(54) PACKAGING BODY, DISPLAY PANEL, AND METHOD OF PACKAGING DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Kun WANG, Wuhan, Hubei (CN)

(21) Appl. No.: 16/613,718

(22) PCT Filed: Sep. 19, 2019
(86) PCT No.: PCT/CN2019/106640

§ 371 Date: Nov. 14, 2019

(30) Foreign Application Priority Data
Jun. 12, 2019 (CN) 201910504077.5

(51) Int. Cl. H01L 51/52; H01L 51/56

(52) U.S. Cl. CPC H01L 51/5253; H01L 2251/303; H01L 51/56

(57) ABSTRACT

A packaging body, a display panel, and a method of packaging a display panel are provided. The packaging body includes a first inorganic layer, a first organic layer, and a second organic layer, and the first inorganic layer, the first organic layer, and the second organic layer are disposed in sequence. The first organic layer is disposed between the second organic layer and the first inorganic layer. Therefore, a thickness of the packaging body of the display panel is reduced, and bending performance of the display panel is improved.

### BACKGROUND OF INVENTION

### Field of Invention

The present invention relates to a field of display technology, and more particularly to a packaging body, a display panel, and a method of packaging a display panel.

### Description of Prior Art

With rapid replacement of electronic products, organic light emitting diode (OLED) devices have advantages of simple structure, fast response times, active illumination, low power consumption, etc., and OLED devices are widely used in display electronic products, such as mobile phones, tablets, televisions, etc. With development of product differentiation, flexible and folding screens are becoming a trend.

In the prior art, a packaging body of the display panel is very thick, and bending performance of the display is rather poor.

### SUMMARY OF INVENTION

In the prior art, a packaging body of the display panel is very thick, and bending performance of the display is not good. Therefore, a packaging body, a display panel, and a method of packaging a display panel are provided.

In one embodiment, a packaging body includes a first inorganic layer, a first organic layer, and a second organic layer. The first organic layer is disposed between the second organic layer and the first inorganic layer.

In one embodiment, the first organic layer includes a plurality of organic sub-layers, and the plurality of organic sub-layers are disposed at intervals on a surface of the first inorganic layer.

In one embodiment, the organic sub-layer is in a droplet shape, and the plurality of organic sub-layers are disposed two-dimensional array arrangement at intervals on the surface of the first inorganic layer; or the organic sub-layer is in a linear shape, and the plurality of organic sub-layers are disposed at intervals on the surface of the first inorganic layer in a one-dimensional array arrangement; or the organic sub-layer is in a closed shape, and the plurality of organic sub-layers are disposed radially at intervals on the surface of the first inorganic layer.

In one embodiment, the organic sub-layer is in a droplet shape, and the plurality of organic sub-layers are disposed two-dimensional array arrangement at intervals on the surface of the first inorganic layer, and a distance between centers of each two adjacent organic sub-layers is less than 300 μm.

In one embodiment, the first organic layer is disposed on a surface of the first inorganic layer and has a curved shape.

In one embodiment, the packaging body further includes a second inorganic layer, the second inorganic layer is disposed on a side of the second organic layer away from the first organic layer, the first inorganic layer comprises at least one of silicon oxide, silicon nitride, zinc oxide, silicon oxynitride, aluminum oxide, and silicon oxycarbonitride, and the second inorganic layer includes at least one of silicon oxide, silicon nitride, zinc oxide, silicon oxynitride, aluminum oxide, and silicon oxycarbonitride.

In one embodiment, the first organic layer and the second organic layer are made of identical materials, and the identical materials are organic silicon compounds.

In one embodiment, the organic silicon compounds are organic compounds comprising silicon-carbon bonds and/or silicon-oxycarbon bonds.

In another embodiment, a display panel includes a substrate and a packaging body, and the packaging body includes a first inorganic layer, a first organic layer, and a second organic layer, and the first organic layer is disposed between the second organic layer and the first inorganic layer.

In one embodiment, the first organic layer includes a plurality of organic sub-layers, and the plurality of organic sub-layers are disposed at intervals on a surface of the first inorganic layer.

In one embodiment, the organic sub-layer is in a droplet shape, and the plurality of organic sub-layers are disposed two-dimensional array arrangement at intervals on the surface of the first inorganic layer; or the organic sub-layer is in a linear shape, and the plurality of organic sub-layers are disposed at intervals on the surface of the first inorganic layer in a one-dimensional array arrangement; or the organic sub-layer is in a closed shape, and the plurality of organic sub-layers are disposed radially at intervals on the surface of the first inorganic layer.

In one embodiment, the organic sub-layer is in a droplet shape, and the plurality of organic sub-layers are disposed two-dimensional array arrangement at intervals on the surface of the first inorganic layer, and a distance between centers of each two adjacent organic sub-layers is less than 300 μm.

In one embodiment, the first organic layer is disposed on a surface of the first inorganic layer and has a curved shape.

In one embodiment, the packaging body further includes a second inorganic layer, the second inorganic layer is disposed on a side of the second organic layer away from the first organic layer, the first inorganic layer includes at least one of silicon oxide, silicon nitride, zinc oxide, silicon oxynitride, aluminum oxide, and silicon oxycarbonitride, and the second inorganic layer includes at least one of silicon oxide, silicon nitride, zinc oxide, silicon oxynitride, aluminum oxide, and silicon oxycarbonitride.

In one embodiment, the first organic layer and the second organic layer are made of identical materials, and the identical materials are organic silicon compounds.

In one embodiment, the organic silicon compounds are organic compounds comprising silicon-carbon bonds and/or silicon-oxycarbon bonds.

In another embodiment, a method of packaging a display panel includes following steps:

providing a substrate;

forming a first inorganic layer on a surface of the substrate; and

forming a first organic layer and a second organic layer in sequence on a side surface of the first inorganic layer away from the substrate, and the first organic layer is disposed between the second organic layer and the first inorganic layer.

In one embodiment, a step of the forming a first organic layer and a second organic layer in sequence on a side surface of the first inorganic layer away from the substrate includes:

spraying a first organic solution on a side surface of the first inorganic layer away from the substrate by inkjet printing to form the first organic layer;

curing the first organic layer; and

forming the second organic layer by the inkjet printing.

In one embodiment, a step of following the formation of a first organic layer and a second organic layer in sequence on a side surface of the first inorganic layer away from the substrate includes:

forming the second inorganic layer on a side of the second organic layer away from the first organic layer.

In one embodiment, a step following the formation of a first organic layer and a second organic layer in sequence on a side surface of the first inorganic layer away from the substrate includes:

forming a second inorganic layer on a side of the second organic layer away from the first organic layer.

A packaging body is provided to be distinct from the prior art. The packaging body includes a first inorganic layer, a first organic layer, and a second organic layer disposed in sequence, and the first organic layer is disposed between the second organic layer and the first inorganic layer. In the embodiment, the first organic layer is disposed between the second organic layer and the first inorganic layer, and thus spreadability and leveling of the second organic layer are improved due to disposing the first inorganic layer. Therefore, a thickness of the second organic layer is significantly reduced, a thickness of the packaging body of the display panel is also reduced, and improves bending performance of the display panel.

### BRIEF DESCRIPTION OF DRAWINGS

In order to more clearly illustrate the technical solutions in the embodiments of the present invention, the drawings used in the description of the embodiments will be briefly described below. It is obvious that the drawings in the following description are only some embodiments of the present invention. Other drawings can also be obtained from those skilled persons in the art based on these drawings without paying any creative effort.

FIG. 1 is a schematic cross-sectional view of a packaging body according to one embodiment of the present invention.

FIG. 2 is a schematic cross-sectional view of a packaging body according to another embodiment of the present invention.

FIG. 3 is a schematic view of an arrangement of the first organic layer of FIG. 2 on the first inorganic layer.

FIG. 4 is a schematic view of an arrangement of a first organic layer on a first inorganic layer in a packaging body according to another embodiment of the present invention.

FIG. 5 is a schematic view of an arrangement of a first organic layer on a first inorganic layer in a packaging body according to another embodiment of the present invention.

FIG. 6 is a schematic view of an arrangement of a first organic layer on a first inorganic layer in a packaging body according to another embodiment of the present invention.

FIG. 7 is a cross-sectional view of a display panel according to one embodiment of the present invention.

FIG. 8 is a schematic flowchart of a method of packaging a display panel according to one embodiment of the present invention.

FIG. 9 is a schematic view of the display panel in S81 of FIG. 8.

FIG. 10 is a schematic view of the display panel in S82 of FIG. 8.

FIG. 11 is a schematic view of the display panel in S83 of FIG. 8.

FIG. 12 is a schematic view of a display panel when forming a second organic layer after S83 of FIG. 8.

### DETAILED DESCRIPTION OF PREFERRED EMBODIMENTS

The technical solutions in the embodiments of the present invention are clearly and completely described in the following with reference to the accompanying drawings in the embodiments of the present invention. It is obvious that the described embodiments are only a part of the embodiments of the present invention, but not all embodiments. All other embodiments obtained by those skilled persons without creative efforts in the art based on the embodiments of the present invention are within the scope of the present invention.

In the description of the present invention, it should be understood that the terms including “center,” “longitudinal,” “lateral,” “length,” “width,” “thickness,” “upper,” “lower,” “front,” “back,” “left,” “right,” “vertical,” “horizontal,” “top,” “bottom,” “inside,” and “outside” are based on the orientation or positional relationship shown in the drawings, and the terms are merely for convenience of description of the present invention and simplified description, and do not indicate or imply the indicated device or the components must have a specific orientation, specific orientation structure, and operation, and thus they are not to be construed as limiting. Moreover, the terms “first” and “second” are only used for describing purposes and are not to be understood as indicating or implying a relative importance or indicating the number of technical features. Thus, features defining “first” and “second” may include one or more of the features either explicitly or implicitly. In the description of the present invention, “a plurality” means two or more unless otherwise stated.

In the present invention, the term “exemplary” is used to mean “serving as an example, instance, or illustration.” Any embodiment described in the present invention as “exemplary” is not necessarily to be construed as preferred or advantageous over other embodiments. In order to make any skilled person in the art to achieve and use the present invention, the following description is presented. In the following description, details are set forth for the purpose of explanation. It will be appreciated that those skilled persons in the art can recognize that the present invention can be practiced without the specific details. In other embodiments, well-known structures and processes are not described in detail to avoid unnecessary detail. Therefore, the present invention is not intended to be limited to the embodiments, but is in accord with the broad scope of the principles and features disclosed herein.

In one embodiment, a packaging body includes a first inorganic layer 11, a first organic layer, and a second organic layer, and the first organic layer is disposed between the second organic layer and the first inorganic layer 11. The packaging body can be applied to various display panels, and the details are described below.

Referring to FIG. 1, it is a schematic cross-sectional view of a packaging body according to one embodiment of the present invention.

In one embodiment, a packaging body 10 includes a first inorganic layer 11, a first organic layer 12, and a second organic layer 13. The first organic layer 12 is disposed between the second organic layer 13 and the first inorganic layer 11, and spreadability and leveling of the second organic layer 13 are improved due to the disposition of the first inorganic layer 11. Therefore, a thickness of the second organic layer 13 is significantly reduced, a thickness of the packaging body 10 of the display panel is also reduced, and bending performance of the display panel is improved. In addition, the first inorganic layer 11 is an entire layer, which can improve moisture resistance of the packaging body 10.

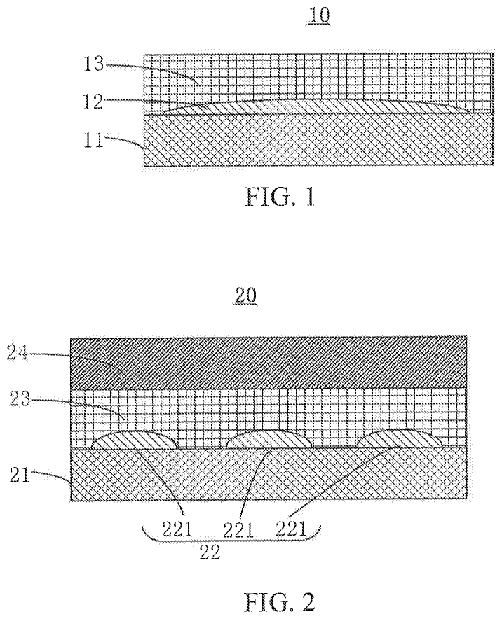

Referring to FIG. 2 and FIG. 3, FIG. 2 is a schematic cross-sectional view of a packaging body according to another embodiment of the present invention, and FIG. 3 is a schematic view of an arrangement of the first organic layer of FIG. 2 on the first inorganic layer.

In one embodiment, a packaging body 20 includes a first inorganic layer 21, a first organic layer 22, and a second organic layer 23. The first organic layer 22 is disposed between the second organic layer 23 and the first inorganic layer 21.

The packaging body 20 further includes a second inorganic layer 24. The second inorganic layer 24 is disposed on a side of the second organic layer 23 away from the first organic layer 22. The first inorganic layer 21 includes at least one of silicon oxide, silicon nitride, zinc oxide, silicon oxynitride, aluminum oxide, and silicon oxycarbonitride. The second inorganic layer 24 includes at least one of silicon oxide, silicon nitride, zinc oxide, silicon oxynitride, aluminum oxide, and silicon oxycarbonitride. Moisture resistance of the packaging body 20 is improved through the arrangement of inorganic layer-organic layer-inorganic layer. In addition, bending performance of the packaging body 20 is also improved.

In a preferred embodiment, the first organic layer 21 and the second organic layer 22 are made of identical materials, and the identical materials are organic silicon compounds. Specifically, the organic silicon compounds are organic compounds including silicon-carbon bonds and/or silicon-oxycarbon bonds. In another embodiment, the first organic layer 21 and the second organic layer 22 are, but not limited to, made of different materials based on actual needs.

The first organic layer 22 includes a plurality of organic sub-layers 221, and the plurality of organic sub-layers 221 are disposed at intervals on a surface of the first inorganic layer 21. Because the plurality of organic sub-layers 221 are disposed at intervals on a surface of the first inorganic layer 21, the first organic layer 22 covers a larger area of the first inorganic layer 21 based on a constant amount of material used by the first organic layer 22. That is, an amount of material used by the first organic layer 22 is reduced, and thus manufacturing costs are lowered.

Furthermore, the organic sub-layer 221 is in a droplet shape, and the plurality of organic sub-layers 221 are disposed two-dimensional array arrangement at intervals on the surface of the first inorganic layer 21. That is, the organic sub-layer 221 is uniformly covered on the first inorganic layer 21. When the second organic layer 23 is formed, the second organic layer 23 is uniformly spread and leveled. Therefore, spreadability and leveling of the second organic layer 23 are improved, and a thickness of the second inorganic layer 24 is reduced so as to improve bending performance of the packaging body 20.

In a preferred embodiment, the organic sub-layer 221 is in a droplet shape, and the plurality of organic sub-layers 221 are disposed two-dimensional array arrangement at intervals on the surface of the first inorganic layer 21. A distance between centers of each two adjacent organic sub-layers 221 is less than 300 μm. A distance between centers of each two adjacent organic sub-layers 221 is less than 300 μm and an amount of material used by the first organic layer 22 is reduced, so the spreadability and leveling of the second organic layer 23 are also improved. Therefore, and an excessive distance between the organic sub-layers 221 causing the spreadability and leveling of the second organic layer 23 to be degraded is prevented.

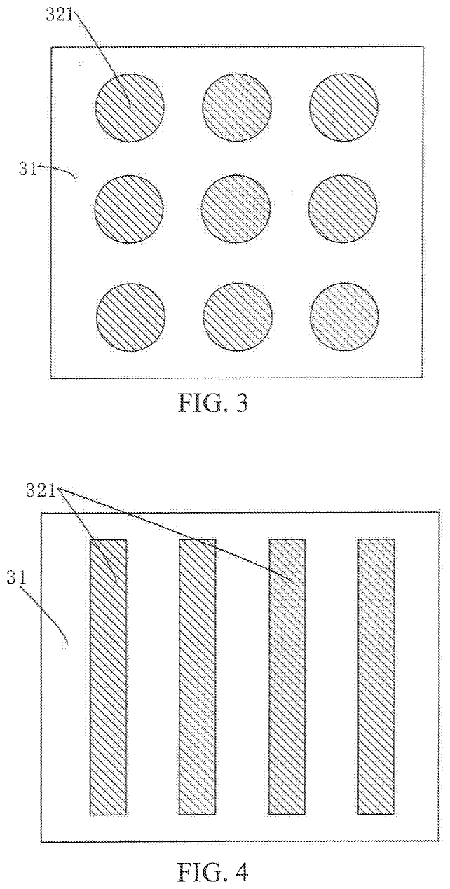

Referring to FIG. 4 to FIG. 6, in order to illustrate the arrangement of a first organic layer on a first inorganic layer in a packaging body, several arrangements of a first organic layer on a first inorganic layer are shown in the FIG. 4 to FIG. 6. In other embodiments, a first organic layer is, but not limited to, disposed on a first inorganic layer in other arrangements.

Referring to FIG. 4, it is a schematic view of an arrangement of a first organic layer on a first inorganic layer in a packaging body according to another embodiment of the present invention.

As shown in FIG. 4, a organic sub-layer 321 is in a linear shape, and a plurality of organic sub-layers 321 are disposed at intervals on a surface of a first inorganic layer 31 in a one-dimensional array arrangement.

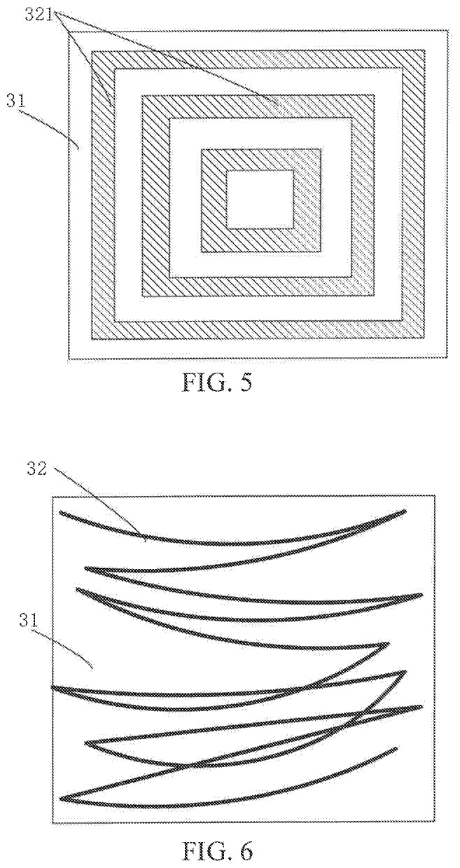

Referring to FIG. 5, it is a schematic view of an arrangement of a first organic layer on a first inorganic layer in a packaging body according to another embodiment of the present invention.

As shown in FIG. 5, the organic sub-layer 321 is in a closed shape, and the plurality of organic sub-layers 321 are disposed radially at intervals on a surface of the first inorganic layer 31.

Referring to FIG. 6, it is a schematic view of an arrangement of a first organic layer on a first inorganic layer in a packaging body according to another embodiment of the present invention.

As shown in FIG. 6, the first organic layer 32 is disposed on a surface of the first inorganic layer 31 and has a curved shape. The curve may be a regular curve, an irregular curve or a combination thereof, and the curve may be a continuous curve or a discontinuous curve, which is not limited herein. Preferably, the first organic layer 32 is formed on the surface of the first inorganic layer 31 by inkjet printing. When the curve is a continuous curve, it can be continuously printed by inkjet printing, thereby improving the manufacturing efficiency.

A packaging body is provided to be distinct from the prior art. The packaging body includes a first inorganic layer, a first organic layer, and a second organic layer disposed in sequence, and the first organic layer is disposed between the second organic layer and the first inorganic layer. In one embodiment, the first organic layer is disposed between the second organic layer and the first inorganic layer, and spreadability and leveling of the second organic layer are improved due to the disposition of the first inorganic layer. Therefore, a thickness of the second organic layer is significantly reduced, a thickness of the packaging body of the display panel is also reduced, and bending performance of the display panel is improved.

Referring to FIG. 7, it is a cross-sectional view of a display panel according to one embodiment of the present invention.

In one embodiment, a display panel 70 includes a substrate 75 which is an organic electroluminescent element. The substrate 75 includes a substrate, a buffer layer, a thin film transistor circuit layer, an organic light emitting layer, a barrier, etc. Material of the substrate includes, but is not limited to, polyimide (PI) or polyethylene terephthalate (PET). In other embodiments, the substrate 75 is, but not limited to, a liquid crystal display element or other type of display element.

Furthermore, the display panel 70 includes a substrate 75, a first inorganic layer 71, a first organic layer 72, a second organic layer 73, and a second inorganic layer 74. The first inorganic layer 71, the first organic layer 72, the second organic layer 73, and the second inorganic layer 74 are disposed on the substrate 75 in sequence. The first organic layer 72 includes a plurality of organic sub-layers 721. The first inorganic layer 71, the first organic layer 72, the second organic layer 73, the second inorganic layer 74, and the plurality of organic sub-layers 721 are identical to the first inorganic layer, the first organic layer, the second organic layer, the second inorganic layer, and the plurality of organic sub-layers as shown in FIG. 1 to FIG. 6, and are not described herein again.

A display panel is provided to be distinct from the prior art. The display panel includes a substrate and a packaging body. The packaging body includes a first inorganic layer, a first organic layer, and a second organic layer disposed in sequence, and the first organic layer is disposed between the second organic layer and the first inorganic layer. In one embodiment, the first organic layer is disposed between the second organic layer and the first inorganic layer, and spreadability and leveling of the second organic layer are improved due to disposition of the first inorganic layer. Therefore, a thickness of the second organic layer is significantly reduced, a thickness of the packaging body of the display panel is also reduced, and bending performance of the display panel is improved.

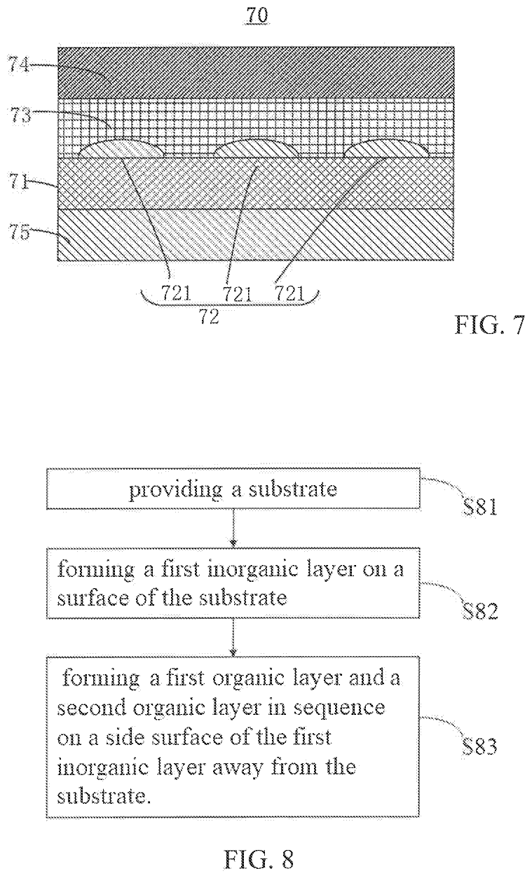

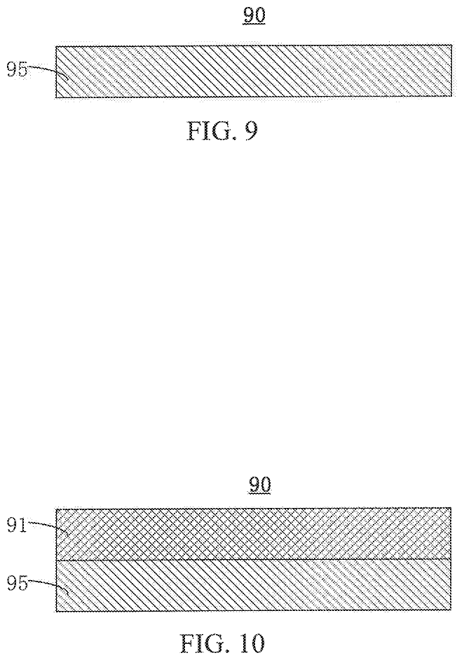

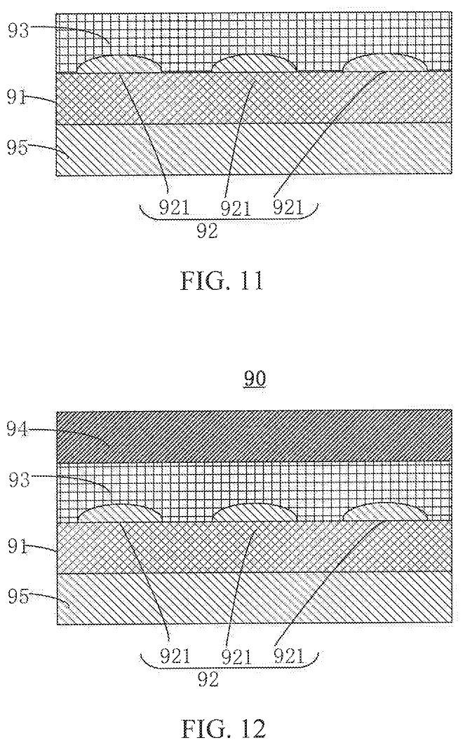

Referring to FIG. 8 to FIG. 12, FIG. 8 is a schematic flowchart of a method of packaging a display panel according to one embodiment of the present invention; FIG. 9 is a schematic view of a display panel in S81 of FIG. 8; FIG. 10 is a schematic view of a display panel in S82 of FIG. 8; FIG. 11 is a schematic view of a display panel in S83 of FIG. 8; and FIG. 12 is a schematic view of a display panel when forming a second organic layer after S83 of FIG. 8.

In one embodiment, a method of packaging a display panel includes steps described as follows.

S81, providing a substrate. As shown in FIG. 9, a substrate 95 is an organic electroluminescent element. The substrate 95 includes a substrate, a buffer layer, a thin film transistor circuit layer, an organic light emitting layer, a barrier, etc. Material of the substrate includes, but is not limited to, polyimide (PI) or polyethylene terephthalate (PET). In other embodiments, the substrate 95 is, but not limited to, a liquid crystal display element or other type of display element.

S82, forming a first inorganic layer on a surface of the substrate. As shown in FIG. 10, a first inorganic layer 91 is deposited on the substrate by atomic layer deposition (ALD), pulsed laser deposition (PLD), plasma enhanced chemical vapor deposition (PECVD), or sputter coating. The first inorganic layer 91 may be the first inorganic layer in any of the above embodiments, and details are not described herein again. Preferably, the first inorganic layer 91 is an entire layer, and the first electrode layer completely covers the substrate 95, and completely blocks out moisture, thereby protecting the display panel 90.

S83, forming a first organic layer and a second organic layer in sequence on a side surface of the first inorganic layer away from the substrate. As shown in FIG. 10 and FIG. 11, spraying a first organic solution on a side surface of the first inorganic layer 91 away from the substrate by inkjet printing to form a first organic layer 92. Then, curing the first organic layer 92, and forming a second organic layer 93 by inkjet printing. In one embodiment, the first organic layer 92 includes a plurality of organic sub-layers 921, and the first organic layer 92, the second organic layer 93, and the plurality of organic sub-layers 921 may be the first organic layer, the second organic layer, and the plurality of organic sub-layers in any of the above embodiments, and are not described herein again. Inkjet printing is a process in which a nozzle draws a probe reagent from a microplate and then the nozzle is moved to the treated support to eject droplets of the prove reagent onto the surface of the support by injector which is driven by thermal power or voice control. In other embodiments, the second organic layer 93 can be directly formed by inkjet printing after spraying the first organic layer 92, so as to improve the manufacturing efficiency, and it is not limited herein. Before forming the second organic layer 93, the first organic layer 92 is formed on the first inorganic layer 95, and spreadability and leveling of the second organic layer 93 are improved due to the disposition the first inorganic layer 92. Therefore, a thickness of the second organic layer 93 is significantly reduced, a thickness of the display panel 90 is also reduced, and bending performance of the display panel 90 is improved. In addition, the first inorganic layer 95 is an entire layer, which can improve moisture resistance of the display panel 90.

Furthermore, as shown in FIG. 12, a second inorganic layer 94 is formed on a side of the second organic layer 93 away from the first organic layer 92 after forming the first organic layer 92 and the second organic layer 93 in sequence on a side surface of the first inorganic layer 91 away from the substrate 95. Specifically, the second inorganic layer 94 can be formed on a side of the second organic layer 93 away from the first organic layer 92 by atomic layer deposition (ALD), pulsed laser deposition (PLD), plasma enhanced chemical vapor deposition (PECVD), or sputter coating. The moisture resistance of the display panel 90 and the bending performance of the display panel 90 are further improved through the arrangement of inorganic layer-organic layer-inorganic layer.

A method of packaging display panel is provided to be distinct from the prior art. The method of packaging display panel includes providing a substrate; forming a first inorganic layer on a surface of the substrate; and forming a first organic layer and a second organic layer in sequence on a side surface of the first inorganic layer away from the substrate, and a projection region of the first organic layer on the first inorganic layer is disposed in a projection area of the second organic layer on the first inorganic layer. In one embodiment, the first organic layer is disposed between the second organic layer and the first inorganic layer, and spreadability and leveling of the second organic layer are improved due to disposition the first inorganic layer. Therefore, a thickness of the second organic layer is significantly reduced, a thickness of the packaging body of the display panel is also reduced, and bending performance of the display panel is improved.

It should be noted that, in the foregoing embodiments, only the foregoing display panel structure is described. It can be understood that, in addition to the foregoing display pane structure, any other necessary structure may be included as needed, and is not limited herein.

In the specific implementation, the foregoing various units or structures may be implemented as a separate entity, or may be implemented in any combination with the same or several entities. For the specific implementation of the above various units or structures can be referred to the foregoing embodiments, and are described again.

In the above, a packaging body, a display panel, and a method of packaging a display panel have been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A packaging body, comprising a first inorganic layer, a first organic layer, and a second organic layer, wherein the first organic layer is disposed between the second organic layer and the first inorganic layer.

2. The packaging body according to claim 1, wherein the first organic layer comprises a plurality of organic sub-layers, and the plurality of organic sub-layers are disposed at intervals on a surface of the first inorganic layer.

3. The packaging body according to claim 2, wherein the organic sub-layer is in a droplet shape, and the plurality of organic sub-layers are disposed two-dimensional array arrangement at intervals on the surface of the first inorganic layer; or
wherein the organic sub-layer is in a linear shape, and the plurality of organic sub-layers are disposed at intervals on the surface of the first inorganic layer in a one-dimensional array arrangement; or
wherein the organic sub-layer is in a closed shape, and the plurality of organic sub-layers are disposed radially at intervals on the surface of the first inorganic layer.

4. The packaging body according to claim 2, wherein the organic sub-layer is a droplet shape, and the plurality of organic sub-layers are disposed two-dimensional array arrangement at intervals on the surface of the first inorganic layer, and a distance between centers of each two adjacent organic sub-layers is less than 300 μm.

5. The packaging body according to claim 1, wherein the first organic layer is disposed on a surface of the first inorganic layer and has a curved shape.

6. The packaging body according to claim 1, wherein the packaging body further comprises a second inorganic layer, the second inorganic layer is disposed on a side of the second organic layer away from the first organic layer, the first inorganic layer comprises at least one of silicon oxide, silicon nitride, zinc oxide, silicon oxynitride, aluminum oxide, and silicon oxycarbonitride, and the second inorganic layer comprises at least one of silicon oxide, silicon nitride, zinc oxide, silicon oxynitride, aluminum oxide, and silicon oxycarbonitride.

7. The packaging body according to claim 1, wherein the first organic layer and the second organic layer are made of identical materials, and the identical materials are organic silicon compounds.

8. The packaging body according to claim 7, wherein the organic silicon compounds are organic compounds comprising silicon-carbon bonds and/or silicon-oxycarbon bonds.

9. A display panel, comprising a substrate and a packaging body, wherein the packaging body comprises a first inorganic layer, a first organic layer, and a second organic layer, and the first organic layer is disposed between the second organic layer and the first inorganic layer.

10. The display panel according to claim 9, wherein the first organic layer comprises a plurality of organic sub-layers, and the plurality of organic sub-layers are disposed at intervals on a surface of the first inorganic layer.

11. The display panel according to claim 10, wherein the organic sub-layer is in a droplet shape, and the plurality of organic sub-layers are disposed two-dimensional array arrangement at intervals on the surface of the first inorganic layer; or
wherein the organic sub-layer is in a linear shape, and the plurality of organic sub-layers are disposed at intervals on the surface of the first inorganic layer in a one-dimensional array arrangement; or
wherein the organic sub-layer is in a closed shape, and the plurality of organic sub-layers are disposed radially at intervals on the surface of the first inorganic layer.

12. The display panel according to claim 10, wherein the organic sub-layer is in a droplet shape, and the plurality of organic sub-layers are disposed two-dimensional array arrangement at intervals on the surface of the first inorganic layer, and a distance between centers of each two adjacent organic sub-layers is less than 300 μm.

13. The display panel according to claim 9, wherein the first organic layer is disposed on a surface of the first inorganic layer and has a curved shape.

14. The display panel according to claim 9, wherein the packaging body further comprises a second inorganic layer, the second inorganic layer is disposed on a side of the second organic layer away from the first organic layer, the first inorganic layer comprises at least one of silicon oxide, silicon nitride, zinc oxide, silicon oxynitride, aluminum oxide, and silicon oxycarbonitride, and the second inorganic layer comprises at least one of silicon oxide, silicon nitride, zinc oxide, silicon oxynitride, aluminum oxide, and silicon oxycarbonitride.

15. The display panel according to claim 9, wherein the first organic layer and the second organic layer are made of identical materials, and the identical materials are organic silicon compounds.

16. The display panel according to claim 15, wherein the organic silicon compounds are organic compounds comprising silicon-carbon bonds and/or silicon-oxycarbon bonds.

17. A method of packaging a display panel, comprising following steps:
providing a substrate;
forming a first inorganic layer on a surface of the substrate; and
forming a first organic layer and a second organic layer in sequence on a side surface of the first inorganic layer away from the substrate, wherein the first organic layer is disposed between the second organic layer and the first inorganic layer.

18. The method of packaging the display panel according to claim 17, wherein a step of the forming a first organic layer and a second organic layer in sequence on a side surface of the first inorganic layer away from the substrate comprises:
spraying a first organic solution on a side surface of the first inorganic layer away from the substrate by inkjet printing to form the first organic layer;
curing the first organic layer; and
forming the second organic layer by the inkjet printing.

19. The method of packaging the display panel according to claim 17, wherein a step of following formation of a first organic layer and a second organic layer in sequence on a side surface of the first inorganic layer away from the substrate comprises:
forming a second inorganic layer on a side of the second organic layer away from the first organic layer.

20. The method of packaging the display panel according to claim 18, wherein step of after the forming a first organic layer and a second organic layer in sequence on a side surface of the first inorganic layer away from the substrate comprises:
forming a second inorganic layer on a side of the second organic layer away from the first organic layer.
